(19) United States
(12) Patent Application Publication
(10) Pub. No.: US 2014/0179056 A1
(43) Pub. Date: Jun. 26, 2014

(54) LASER-ABSORBING SEED LAYER FOR SOLAR CELL CONDUCTIVE CONTACT

(71) Applicant: Michael Morse, San Jose, CA (US)

(72) Inventor: Michael Morse, San Jose, CA (US)

(21) Appl. No.: 13/724,152

(22) Filed: Dec. 21, 2012

(51) Int. Cl. H01L 31/02; H01L 31/18

(52) U.S. Cl. CPC H01L 31/02002; H01L 31/182
USPC 438/97; 438/98

(57) ABSTRACT

Laser-absorbing seed layers for solar cell conductive contacts and methods of forming solar cell conductive contacts are described. For example, a method of fabricating a solar cell includes forming a metal seed paste above a substrate. The metal seed paste includes a laser-absorbing species. The metal seed paste is irradiated with a laser to form a metal seed layer. The irradiating includes exciting the laser-absorbing species. A conductive contact for the solar cell is then formed from the metal seed layer.

### TECHNICAL FIELD

Embodiments of the present invention are in the field of renewable energy and, in particular, laser absorbing seed layers for solar cell conductive contacts and methods of forming solar cell conductive contacts.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present invention allow for increased solar cell manufacture efficiency by providing novel processes for fabricating solar cell structures. Some embodiments of the present invention allow for increased solar cell efficiency by providing novel solar cell structures.

### BRIEF DESCRIPTION OF THE DRAWINGS

FIGS. 1A-1C illustrate cross-sectional views of various operations in a method of fabricating a contact for a solar cell, in accordance with an embodiment of the present invention.

FIG. 2A illustrates a cross-sectional view of a portion of a solar cell having conductive contacts formed on emitter regions formed above a substrate, in accordance with an embodiment of the present invention.

FIG. 2B illustrates a cross-sectional view of a portion of a solar cell having conductive contacts formed on emitter regions formed in a substrate, in accordance with another embodiment of the present invention.

FIGS. 3A-3C illustrate cross-sectional views of various processing operations in a method of fabricating solar cells having conductive contacts, in accordance with an embodiment of the present invention.

### DETAILED DESCRIPTION

Laser-absorbing seed layers for solar cell conductive contacts and methods of forming solar cell conductive contacts are described herein. In the following description, numerous specific details are set forth, such as specific process flow operations, in order to provide a thorough understanding of embodiments of the present invention. It will be apparent to one skilled in the art that embodiments of the present invention may be practiced without these specific details. In other instances, well-known fabrication techniques, such as lithography and patterning techniques, are not described in detail in order to not unnecessarily obscure embodiments of the present invention. Furthermore, it is to be understood that the various embodiments shown in the figures are illustrative representations and are not necessarily drawn to scale.

Disclosed herein are methods of fabricating conductive contacts for solar cells. In an embodiment, a method of fabricating a solar cell includes forming a metal seed paste disposed above a substrate. The metal seed paste includes a laser-absorbing species. The metal seed paste is irradiated with a laser to form a metal seed layer. The irradiating includes exciting the laser-absorbing species. A conductive contact for the solar cell is then formed from the metal seed layer where it is in proximity of the silicon. In another embodiment, a method of fabricating a solar cell includes forming a metal seed paste on an emitter region disposed above a substrate. The metal seed paste includes a laser-absorbing species, and the emitter region includes a doped polycrystalline silicon layer. The metal seed paste is irradiated with a laser to form a metal seed layer. The irradiating includes exciting the laser-absorbing species. A conductive back-contact is then formed from the metal seed layer for the emitter region of the solar cell. In yet another embodiment, a method of fabricating a solar cell includes forming a metal seed paste on a surface of an N-type or P-type doped region of an N-type bulk crystalline silicon substrate. The metal seed paste includes a laser-absorbing species. The metal seed paste is irradiated with a laser to form a metal seed layer. The irradiating includes exciting the laser-absorbing species. A conductive back-contact is formed for the N-type or P-type doped region of the substrate from the metal seed layer. Also disclosed herein are compositions for seed layers for forming contacts on solar cells. In an embodiment, a composition includes aluminum/silicon (Al/Si) particles, binders and frit, a solvent, and a laser-absorbing species.

One or more embodiments of the present invention are directed to laser annealing of a printed seed layer having a laser absorber species therein. For example, an economical way perform a module level metallization process flow includes printing a metal seed layer following formation of an encapsulant material. Such an approach can be used whether or not a plating step or a back sheet was applied next. An issue with applying a metal ink or paste on an encapsulant, however, is that performing a thermal anneal to reduce the resistance of the paste may not be possible without degradation of the encapsulant material. In a specific example, an encapsulant material decomposes at approximately 150 degrees Celsius, while a metal paste may need thermal annealing at a temperature approximately in the range of 200-500 degrees Celsius.

To address the above, one or more embodiments involve annealing a metal paste with a laser. To enhance the laser annealing, absorbers can be included in the metal paste to enhance absorbing of the laser energy. By enhancing the absorbing ability of the paste, an annealing may be able to be performed more quickly, since the heating would occur faster. And, possibly, damage to underlying, overlying or adjacent materials can be avoided since the laser radiation would be attenuated or prevented from reaching the material.

In an exemplary embodiment, following opening up of contact holes in an insulating layer (such as a bottom anti-reflective coating layer) on a back side of a solar cell, a plurality of cells can be disposed on glass and encapsulant layers without use of a back sheet. A low cost metal material (e.g., referred to as a paste) is deposited on the back of the cells and over the encapsulant to ultimately fabricate contacts or interconnects for the cells. The process can be performed with a single tool, leading to decreased aggregate processing time and tool cost. In a specific embodiment, the paste includes an absorber to enhance absorption of light at a particular wavelength of light which is matched to a subsequent laser annealing operation.

In the above exemplary embodiment, the laser annealing operation involves scanning a laser over the metal paste lines, annealing the metal paste such that resistivity drops in the paste. The resulting annealed paste can be used as a metal seed layer for plating (as described in greater detail below) or, possibly, to carry current to regional collection points of a metallized back sheet. In the latter case, for example, lower metal densities may be enabled by channeling the cell current to specific points in the module.

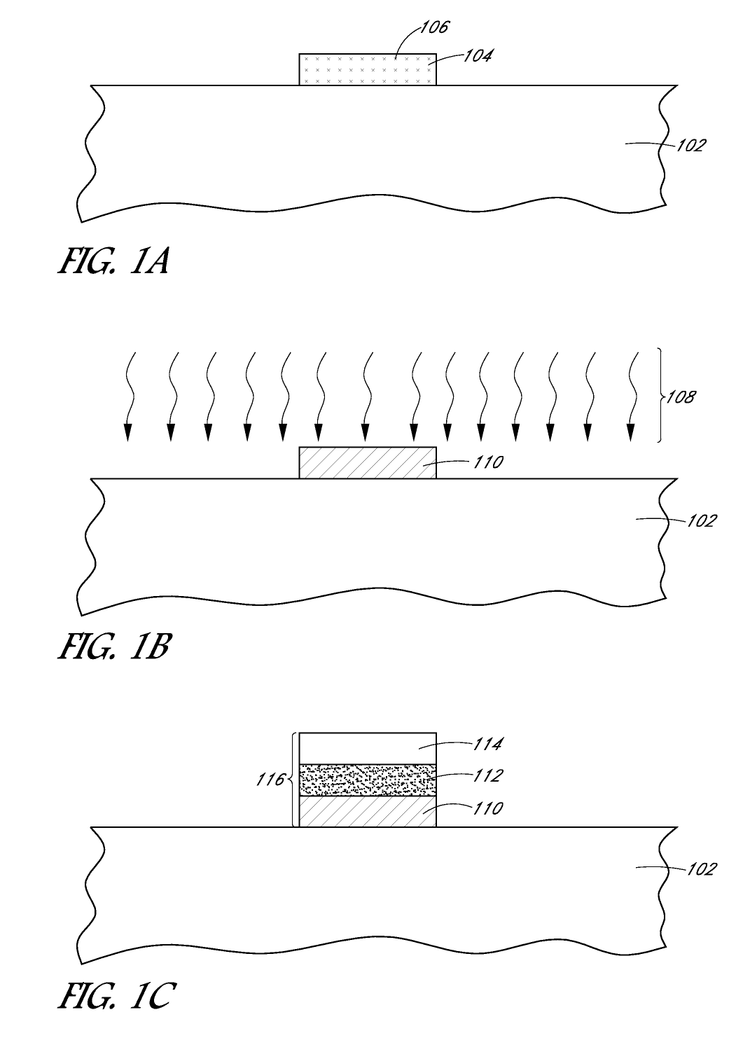

As a general overview of an application of embodiments described herein, FIGS. 1A-1C illustrate cross-sectional views of various operations in a method of fabricating a contact for a solar cell, in accordance with an embodiment of the present invention.

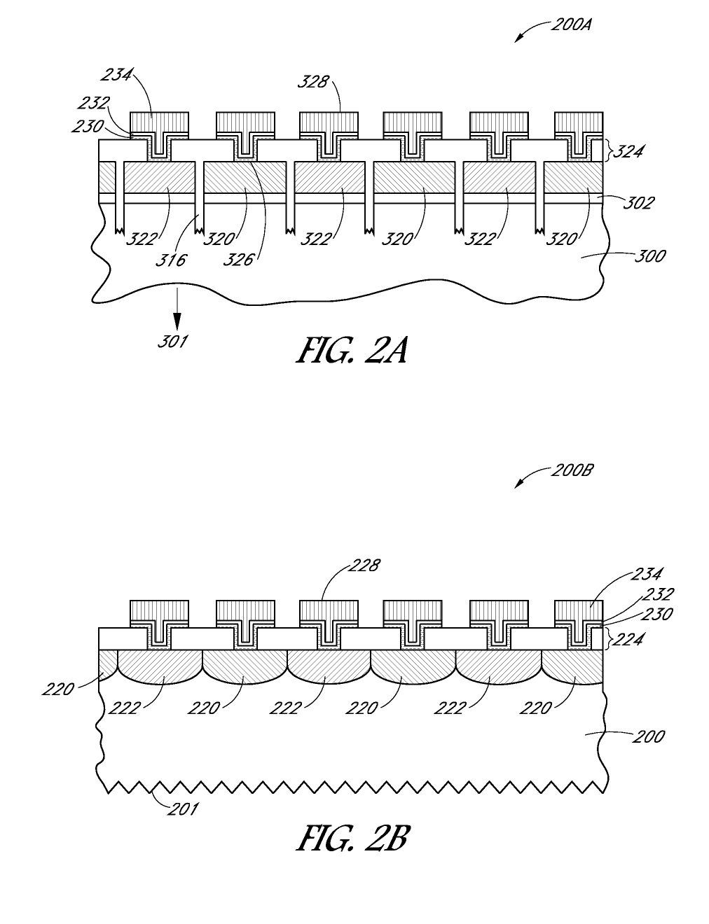

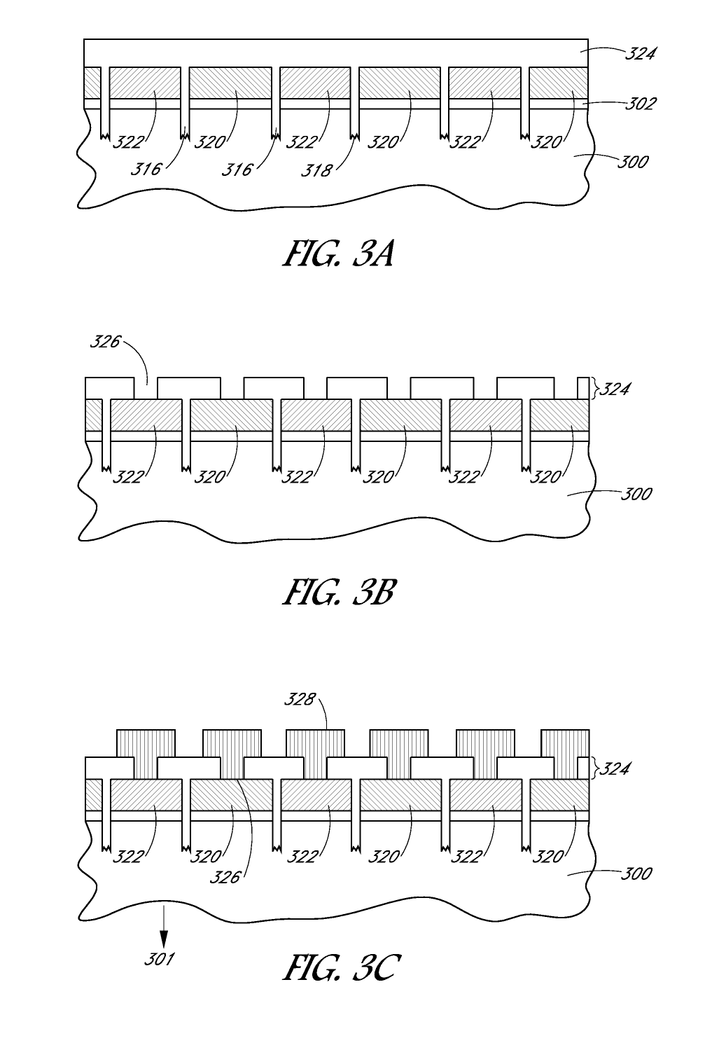

Referring to FIG. 1A, a method of fabricating a solar cell includes forming a metal seed paste 104 above a substrate 102. The metal seed paste 102 includes a laser-absorbing species 106. In one embodiment, the metal seed paste 104 is formed on an emitter region disposed above a substrate, as described in greater detail below in association with FIGS. 2A and 3A-3C. The emitter region can be composed of, e.g., a doped polycrystalline silicon layer. In another embodiment, however, the metal seed paste 104 is formed on a surface of an N-type or P-type doped region of a bulk crystalline silicon substrate, as described in greater detail below in association with FIG. 2B. The bulk crystalline silicon substrate can be, e.g., an N-type bulk crystalline silicon substrate.

In an embodiment, the metal seed paste 104 is composed aluminum/silicon (Al/Si) particles, binders, frit, a solvent, and the laser-absorbing species 106. In one such embodiment, the laser-absorbing species 106 is not bound to the Al/Si particles. In another embodiment, however, the laser-absorbing species 106 is bound to the Al/Si particles. In one embodiment, the Al/Si particles are composed of less than approximately 25% Si, with the remainder of the composition made up by Al. In one embodiment, if included, the binders can be composed of zinc oxide (ZnO), tin oxide (SnO), or both, and the frit can be composed of glass particles.

The metal seed paste 104 can be formed in a global deposition or as a patterned deposition, as depicted in FIG. 1A. For example, in an embodiment, the metal seed paste 104 is formed on or above substrate 102 by printing using a technique such as, but not limited to, screen printing or ink-jet printing. In an embodiment, the laser-absorbing species 106 included in metal seed paste 104 are light-absorbing nano-particles suitable for laser absorption, as described below in association with FIG. 1B.

Referring to FIG. 1B, the method of fabricating the solar cell further includes irradiating 108 the metal seed paste 104 with a laser to form a metal seed layer 110 on or above the substrate 102.

In an embodiment, the irradiating 108 involves exciting the laser-absorbing species 106 of the metal seed paste 104. In one such embodiment, during the irradiating process 108, the metal seed paste 104 is annealed by localized heating generated from exciting the laser-absorbing species 106. In a specific such embodiment, the laser absorbing species 106 is volatilized during the annealing and, thus, substantially not present in the resulting metal seed layer 110. In another specific embodiment, however, following the annealing, the laser absorbing species 106 is substantially present in the resulting metal seed layer 110. In an embodiment, the irradiating 108 involves matching a wavelength of a laser with an absorbance maxima peak of the laser-absorbing species 106. For example, in a specific embodiment, the laser-absorbing species 106 are light-absorbing nano-particles, and exciting the laser-absorbing species 106 involves pulsing the laser while scanning the laser across the light-absorbing nano-particles. The laser has a wavelength that is matched with an absorbance maxima peak of the light-absorbing nano-particles.

The irradiating 108 can be performed adjacent to, or in the presence of, materials having otherwise low decomposition or transition temperatures. The localized heating of the laser process ensures that such materials are not overheated, e.g., as can be the case with a more globalized heating process such as thermal annealing. For example, in an embodiment, the irradiating 108 of the metal seed paste 104 with the laser involves performing the irradiating adjacent a material having a decomposition or melting temperature of approximately 150 degrees Celsius. In a specific such embodiment, the material is an encapsulant layer disposed adjacent to the metal seed paste 104, an example of which is described below in association with FIG. 3C. In another specific such embodiment, the material is an encapsulant layer formed over the metal seed paste 104, and the irradiating 108 involves irradiating through the encapsulant layer without causing damage to the encapsulant layer. In another specific embodiment, the material is an encapsulant layer included on a side of the substrate opposite the metal seed paste 104, and the irradiating 108 involves irradiating above the encapsulant layer without causing damage to the encapsulant layer. In an embodiment, subsequent to forming the metal seed paste 104 on or above the substrate 102 and prior to irradiating 108 the metal seed paste 104 with the laser, the metal seed paste 104 is dried by removing a solvent from the metal seed paste. However, in another embodiment, any solvent present in metal seed paste 104 is removed, e.g., by volatilization, during the irradiating 108.

Referring to FIG. 1C, the method of fabricating the solar cell further includes forming a conductive contact for the solar cell from the metal seed layer 110. In an embodiment, a conductive back-contact is formed for an emitter region disposed above a substrate of the solar cell, e.g., on a polysilicon region, as described in greater detail below in association with FIGS. 2A and 3A-3C. In another embodiment, a conductive back-contact is formed for an N-type or P-type doped region of the substrate, as described in greater detail below in association with FIG. 2B.

In an exemplary embodiment, referring again to FIG. 1C, a conductive contact 116 is formed by electroless plating a nickel (Ni) layer 112 on the metal seed layer 110 subsequent to irradiating 108 the metal seed paste 104 with the laser. A copper (Cu) layer 114 is then electroplated on the Ni layer 112. In one such embodiment, the metal seed layer 104 is originally formed to have a thickness approximately in the range of 0.5-50 microns.

As described briefly above, in a first aspect, a metal seed paste that includes a laser-absorbing species can be used to ultimately fabricate contacts, such as back-side contacts, for a solar cell having emitter regions formed above a substrate of the solar cell. For example, FIG. 2A illustrates a cross-sectional view of a portion of a solar cell having conductive contacts formed on emitter regions formed above a substrate, in accordance with an embodiment of the present invention.

Referring to FIG. 2A, a portion of a solar cell 200A includes a patterned insulating layer 324 disposed above a plurality of n-type doped polysilicon regions 320, a plurality of p-type doped polysilicon regions 322, and on portions of a substrate 300 exposed by trenches 316. Conductive contacts 328 are disposed in a plurality of contact openings disposed in the insulating layer 324 and are coupled to the plurality of n-type doped polysilicon regions 320 and to the plurality of p-type doped polysilicon regions 322. The materials of, and methods of fabricating, the patterned dielectric layer, the plurality of n-type doped polysilicon regions 320, the plurality of p-type doped polysilicon regions 322, the substrate 300, and the trenches 316 may be as described below in association with FIGS. 3A-3C. Furthermore, the plurality of n-type doped polysilicon regions 320 and the plurality of p-type doped polysilicon regions 322 can, in one embodiment, provide emitter regions for the solar cell 200A. Thus, in an embodiment, the conductive contacts 328 are disposed on the emitter regions. In an embodiment, the conductive contacts 328 are back contacts for a back-contact solar cell and are situated on a surface of the solar cell opposing a light receiving surface (direction provided as 301 in FIG. 2A) of the solar cell 200A. Furthermore, in one embodiment, the emitter regions are formed on a thin or tunnel dielectric layer 302, described in greater detail in association with FIG. 3A.

In an embodiment, referring again to FIG. 2A, each of the conductive contacts 328 includes a metal seed layer 230 in contact with the emitter regions of the solar cell 200A. In one such embodiment, the metal seed layer 230 of contact 328 is composed of aluminum/silicon (Al/Si) particles, binders, and frit. In a specific embodiment, an initially included laser-absorbing species not bound to the Al/Si particles is removed in a laser anneal process and, accordingly, is not present in the final composition of metal seed layer 230 of contact 328. In another specific embodiment, however, the laser-absorbing species is bound to the Al/Si particles and, accordingly is not present in the final composition of metal seed layer 230 of contact 328.

In an embodiment, the metal seed layer 230 has a total composition including approximately 10-30% binders and frit, with the remainder the Al/Si particles and, possibly, and remaining laser-absorbing species. In one such embodiment, the binders are composed of zinc oxide (ZnO), tin oxide (SnO), or both, and the frit includes glass particles. It is to be understood that, when initially applied, a seed layer (e.g., an as-applied layer 230) further includes a solvent. However, the solvent can be removed upon annealing the seed layer, leaving essentially the binders, frit and Al/Si particles (and any remaining laser-absorbing species) disposed on the plurality of n-type doped polysilicon regions 320 and the plurality of p-type doped polysilicon regions 322.

In an embodiment (not shown), the metal seed layer 230 has a thickness greater than approximately 50 microns, and the conductive contact 328 fabricated there from is a back contact of the solar cell composed essentially of only the metal seed layer 230. In such an embodiment, the seed layer is not actually a seeding layer used for subsequent plating, as is the case in other embodiments. However, in another embodiment, the metal seed layer 230 has a thickness of approximately 0.5-50 microns. In that embodiment, the conductive contact 328 is a back contact of the solar cell and is composed of the metal seed layer 230, an electroless plated nickel (Ni) layer 232 disposed on the metal seed layer 230, and an electroplated copper (Cu) layer 234 disposed on the Ni layer, as depicted in FIG. 2A.

As also described briefly above, in a second aspect, a metal seed paste that includes a laser-absorbing species can be used to ultimately fabricate contacts, such as back-side contacts, for a solar cell having emitter regions formed in a substrate of the solar cell. For example, FIG. 2B illustrates a cross-sectional view of a portion of a solar cell having conductive contacts formed on emitter regions formed in a substrate, in accordance with an embodiment of the present invention.

Referring to FIG. 2B, a portion of a solar cell 200B includes a patterned insulating layer 224 disposed above a plurality of n-type doped diffusion regions 220, a plurality of p-type doped diffusion regions 222, and on portions of a substrate 200, such as a bulk crystalline silicon substrate. Conductive contacts 228 are disposed in a plurality of contact openings disposed in the insulating layer 224 and are coupled to the plurality of n-type doped diffusion regions 220 and to the plurality of p-type doped diffusion regions 222. In an embodiment, the diffusion regions 220 and 222 are formed by doping regions of a silicon substrate with n-type dopants and p-type dopants, respectively. Furthermore, the plurality of n-type doped diffusion regions 220 and the plurality of p-type doped diffusion regions 222 can, in one embodiment, provide emitter regions for the solar cell 200B. Thus, in an embodiment, the conductive contacts 228 are disposed on the emitter regions. In an embodiment, the conductive contacts 228 are back contacts for a back-contact solar cell and are situated on a surface of the solar cell opposing a light receiving surface, such as opposing a texturized light receiving surface 201, as depicted in FIG. 2B.

In an embodiment, referring again to FIG. 2B, each of the conductive contacts 228 includes a metal seed layer 230 in contact with the emitter regions of the solar cell 200B. In one such embodiment, the metal seed layer 230 of contact 228 is composed of aluminum/silicon (Al/Si) particles, binders, and frit. In a specific embodiment, an initially included laser-absorbing species not bound to the Al/Si particles is removed in a laser anneal process and, accordingly, is not present in the final composition of metal seed layer 230 of contact 228. In another specific embodiment, however, the laser-absorbing species is bound to the Al/Si particles and, accordingly is not present in the final composition of metal seed layer 230 of contact 228.

In an embodiment, the metal seed layer 230 has a total composition including approximately 10-30% binders and frit, with the remainder the Al/Si particles and, possibly, and remaining laser-absorbing species. In one such embodiment, the binders are composed of zinc oxide (ZnO), tin oxide (SnO), or both, and the frit is composed of glass particles. It is to be understood that, when initially applied, a seed layer (e.g., an as-applied layer 230) further includes a solvent. However, the solvent can be removed upon annealing the seed layer, leaving essentially the binders, frit (optional) and Al/Si particles (and any remaining laser-absorbing species) disposed on the diffusion regions 220 and 222.

In an embodiment (not shown), the metal seed layer 230 has a thickness greater than approximately 50 microns, and the conductive contact 228 fabricated there from is a back contact of the solar cell composed essentially of only the metal seed layer 230. As mentioned above, in such an example, the seed layer is not actually used for subsequent seeding during an electroplating process, as is the case for other embodiments. However, in another embodiment, the metal seed layer 230 has a thickness of approximately 0.5-50 microns. In that embodiment, the conductive contact 228 is a back contact of the solar cell and is composed of the metal seed layer 230, an electroless plated nickel (Ni) layer 232 disposed on the metal seed layer 230, and an electroplated copper (Cu) layer 234 disposed on the Ni layer, as depicted in FIG. 2B.

Referring again to FIG. 1A, and pertaining to FIGS. 2A and 2B, in an embodiment, a partially fabricated solar cell includes a substrate, an emitter region disposed in or above the substrate, and a metal seed paste that includes a laser-absorbing species. The metal seed paste is disposed on a silicon region of the emitter region (e.g., disposed on a polysilicon layer or on a silicon substrate). In one such embodiment, the metal seed paste is annealed by irradiating with a laser, as described in association with FIG. 1B. The irradiating can remove the laser-absorbing species such that the laser-absorbing species is not present (at least not substantially present) in the metal seed layer 230 of the final structure 200A or 200B of FIGS. 2A and 2B, respectively. Alternatively, the irradiating may not remove the laser-absorbing species such that the laser-absorbing species is present (at least substantially present) in the metal seed layer 230 of the final structure 200A or 200B of FIGS. 2A and 2B, respectively.

The use of a metal seed paste that includes a laser-absorbing species can allow for localized annealing of the metal seed paste layer such that an adjacent, underlying or overlying temperature sensitive film does is not impacted or degraded during annealing of the metal seed paste. For example, in a first embodiment, referring to FIG. 2A as a reference, a solar cell includes an emitter region with an insulating layer 324 disposed thereon and between conductive contacts 328 which were fabricated using a metal seed paste. In one such embodiment, the insulating layer 324 is thermally sensitive but is not degraded by an earlier localized laser irradiating anneal of the metal seed paste. In another example, in a second embodiment, referring to FIG. 2B as a reference, a solar cell is fabricated from a bulk crystalline silicon substrate, and conductive contacts formed from a metal seed paste are disposed in trenches of an insulating layer 224 disposed above the surface of the substrate. In one such embodiment, the insulating layer 324 is thermally sensitive but is not degraded by an earlier localized laser irradiating anneal of the metal seed paste. In other embodiments, one or more temperature-sensitive encapsulant layers are included above or below the substrate having the metal seed paste thereon. The encapsulant is not degraded by an earlier localized laser irradiating anneal of the metal seed paste.

Although certain materials are described specifically above, some materials may be readily substituted with others with other such embodiments remaining within the spirit and scope of embodiments of the present invention. For example, in an embodiment, a different material substrate, such as a group III-V material substrate, can be used instead of a silicon substrate. In another embodiment, silver (Ag) particles or the like can be used in a seed paste instead of, or in addition to, Al particles. In another embodiment, plated or like-deposited cobalt (Co) can be used instead of or in addition to the plated Ni described above. Similarly, a tungsten (W) layer disposed over the substrate can provide the same function.

Furthermore, the formed contacts need not be formed directly on a bulk substrate, as was described in FIG. 2B. For example, in one embodiment, conductive contacts such as those described above are formed on semiconducting regions formed above (e.g., on a back side of) a bulk substrate, as was described for FIG. 2A. As an example, FIGS. 3A-3C illustrate cross-sectional views of various processing operations in a method of fabricating solar cells having conductive contacts, in accordance with an embodiment of the present invention.

Referring to FIG. 3A, a method of forming contacts for a back-contact solar cell includes forming a thin dielectric layer 302 on a substrate 300.

In an embodiment, the thin dielectric layer 302 is composed of silicon dioxide and has a thickness approximately in the range of 5-50 Angstroms. In one embodiment, the thin dielectric layer 302 ultimately performs as a tunneling oxide layer in a functioning solar cell. In an embodiment, substrate 300 is a bulk single-crystal substrate, such as an n-type doped single crystalline silicon substrate. However, in an alternative embodiment, substrate 300 includes a polycrystalline silicon layer disposed on a global solar cell substrate.

Referring again to FIG. 3A, trenches 316 are formed between n-type doped polysilicon regions 320 and p-type doped polysilicon regions 322. Portions of the trenches 316 can be texturized to have textured features 318, as is also depicted in FIG. 3A.

Referring again to FIG. 3A, a insulating layer 324 is formed above the plurality of n-type doped polysilicon regions 320, the plurality of p-type doped polysilicon regions 322, and the portions of substrate 300 exposed by trenches 316. In one embodiment, a lower surface of the insulating layer 324 is formed conformal with the plurality of n-type doped polysilicon regions 320, the plurality of p-type doped polysilicon regions 322, and the exposed portions of substrate 300, while an upper surface of insulating layer 324 is substantially flat, as depicted in FIG. 3A. In a specific embodiment, the insulating layer 324 is an anti-reflective coating (ARC) layer. In an embodiment, the insulating layer 324 is a thermally sensitive layer having a decomposition point as low as approximately 150 degrees Celsius.

Referring to FIG. 3B, a plurality of contact openings 326 are formed in the insulating layer 324. The plurality of contact openings 326 provide exposure to the plurality of n-type doped polysilicon regions 320 and to the plurality of p-type doped polysilicon regions 322. In one embodiment, the plurality of contact openings 326 is formed by laser ablation. In one embodiment, the contact openings 326 to the n-type doped polysilicon regions 320 have substantially the same height as the contact openings to the p-type doped polysilicon regions 322, as depicted in FIG. 3B.

Referring to FIG. 3C, the method of forming contacts for the back-contact solar cell further includes forming conductive contacts 328 in the plurality of contact openings 326 and coupled to the plurality of n-type doped polysilicon regions 320 and to the plurality of p-type doped polysilicon regions 322. In an embodiment, the conductive contacts 328 are composed of metal and are formed by a deposition (the deposition described in greater detail below), lithographic, and etch approach.

Thus, in an embodiment, conductive contacts 328 are formed on or above a surface of a bulk N-type silicon substrate 300 opposing a light receiving surface 301 of the bulk N-type silicon substrate 300. In a specific embodiment, the conductive contacts are formed on regions (322/320) above the surface of the substrate 300, as depicted in FIG. 3C. The fabrication of the conductive contacts can involve use of a metal seed paste that is subjected to laser irradiation, where laser-absorbing species in the paste are used to absorb the irradiation and locally heat the paste to anneal the paste to form a metal seed layer. Forming the conductive contacts can further include forming an electroless plated nickel (Ni) layer on the metal seed layer. Additionally, a copper (Cu) layer can be formed by electroplating on the Ni layer.

In an embodiment, forming the metal seed layer includes printing a paste on a bulk N-type silicon substrate or on a polysilicon layer formed above such as substrate. The paste can be composed of a solvent, aluminum/silicon (Al/Si) alloy particles, and laser-absorbing species. The printing includes using a technique such as, but not limited to, screen printing or ink-jet printing. Additionally, one or more embodiments described herein are directed to approaches to, and structures resulting from, reducing the contact resistance of printed Al/Si seed formed on a silicon substrate by incorporating the electroless-plated Ni therein. More specifically, one or more embodiments are directed to contact formation starting with an Al-based paste seed layer. Annealing by laser is performed after seed printing to form contact between Al from the paste and an underlying silicon substrate or layer. Then Ni is deposited by electroless plating on top of the resulting Al-based seed layer. Since the Al-based seed layer can have a porous structure, in an embodiment, the Ni forms not only above, but also on the outside of the Al particles, and fills up at least a portion of the empty space. In a specific such embodiment, a zincate activation operation is also used in this process. The Ni may be graded in that more Ni may form on upper portions of the Al (away from the Si). Nonetheless, the Ni on the outside of the Al particles can be utilized to reduce the contact resistance of a contact ultimately formed there from. In particular, if the thickness of the Al-based seed layer is generally reduced, more Ni can accumulate at the Al to silicon interface. Compared to conventional approaches, the contacts formed can have a greater surface area of actual metal to silicon contact within a given region of the contact structure formation. As a result, the contact resistance can be lowered relative to conventional contacts.

Thus, laser-absorbing seed layers for solar cell conductive contacts and methods of forming solar cell conductive contacts have been disclosed. In accordance with an embodiment of the present invention, a method of fabricating a solar cell includes forming a metal seed paste above a substrate. The metal seed paste includes a laser-absorbing species. The metal seed paste is irradiated with a laser to form a metal seed layer. The irradiating includes exciting the laser-absorbing species. A conductive contact for the solar cell is then formed from the metal seed layer. In one embodiment, the method further includes, subsequent to irradiating the metal seed paste with the laser, electroless plating a nickel (Ni) layer on the metal seed layer, and electroplating a copper (Cu) layer on the Ni layer.

1. A method of fabricating a solar cell, the method comprising:
forming a metal seed paste above a substrate, the metal seed paste comprising a laser-absorbing species;
irradiating the metal seed paste with a laser to form a metal seed layer, the irradiating comprising exciting the laser-absorbing species; and
forming a conductive contact for the solar cell from the metal seed layer.

2. The method of claim 1, wherein irradiating the metal seed paste with the laser comprises annealing the metal seed paste by localized heating generated from exciting the laser-absorbing species.

3. The method of claim 2, wherein annealing the metal seed paste comprises volatilizing the laser-absorbing species.

4. The method of claim 1, wherein irradiating the metal seed paste with the laser comprises matching a wavelength of the laser with an absorbance maxima peak of the laser-absorbing species.

5. The method of claim 1, wherein irradiating the metal seed paste with the laser comprises performing the irradiating adjacent a material having a decomposition or melting temperature of approximately 150 degrees Celsius.

6. The method of claim 5, wherein the material is an encapsulant layer formed over the metal seed paste, and wherein irradiating the metal seed paste with the laser comprises irradiating through the encapsulant layer without causing damage to the encapsulant layer.

7. The method of claim 1, wherein forming the metal seed paste comprises forming a composition comprising aluminum/silicon (Al/Si) particles, binders, a solvent, and the laser-absorbing species.

8. The method of claim 7, wherein forming the composition comprises printing the composition using a technique selected from the group consisting of screen printing and ink-jet printing.

9. The method of claim 1, wherein forming the conductive contact further comprises:
subsequent to irradiating the metal seed paste with the laser, electroless plating a nickel (Ni) layer on the metal seed layer; and
electroplating a copper (Cu) layer on the Ni layer.

10. The method of claim 1, wherein forming the metal seed layer comprises forming a conductive seed layer having a thickness approximately in the range of 0.5-50 microns.

11. The method of claim 1, further comprising:
subsequent to forming the metal seed paste above the substrate and prior to irradiating the metal seed paste with the laser, drying the metal seed paste by removing a solvent from the metal seed paste.

12. The method of claim 1, wherein the laser-absorbing species are light-absorbing nano-particles, and wherein exciting the laser-absorbing species comprises pulsing the laser while scanning the laser across the light-absorbing nano-particles.

13. A method of fabricating a solar cell, the method comprising:
forming a metal seed paste on an emitter region disposed above a substrate, the metal seed paste comprising a laser-absorbing species, and the emitter region comprising a doped polycrystalline silicon layer;
irradiating the metal seed paste with a laser to form a metal seed layer, the irradiating comprising exciting the laser-absorbing species; and
forming a conductive back-contact for the emitter region of the solar cell from the metal seed layer.

14. The method of claim 13, wherein irradiating the metal seed paste with the laser comprises annealing the metal seed paste by localized heating generated from exciting the laser-absorbing species.

15. The method of claim 13, wherein forming the conductive back-contact further comprises:
subsequent to irradiating the metal seed paste with the laser, electroless plating a nickel (Ni) layer on the metal seed layer; and
electroplating a copper (Cu) layer on the Ni layer.

16. The method of claim 13, wherein forming the metal seed layer comprises forming a conductive seed layer having a thickness approximately in the range of 0.5-50 microns.

17. A method of fabricating a solar cell, the method comprising:
forming a metal seed paste on a surface of an N-type or P-type doped region of an N-type bulk crystalline silicon substrate, the metal seed paste comprising a laser-absorbing species;
irradiating the metal seed paste with a laser to form a metal seed layer, the irradiating comprising exciting the laser-absorbing species; and
forming a conductive back-contact for the N-type or P-type doped region of the substrate from the metal seed layer.

18. The method of claim 17, wherein irradiating the metal seed paste with the laser comprises annealing the metal seed paste by localized heating generated from exciting the laser-absorbing species.

19. The method of claim 17, wherein forming the conductive back-contact further comprises:
subsequent to irradiating the metal seed paste with the laser, electroless plating a nickel (Ni) layer on the metal seed layer; and
electroplating a copper (Cu) layer on the Ni layer.

20. The method of claim 17, wherein forming the metal seed layer comprises forming a conductive seed layer having a thickness approximately in the range of 0.5-50 microns.

21-25. (canceled)
